(19) United States
(12) Patent Application Publication
(10) Pub. No.: US 2006/0109631 A1
(43) Pub. Date: May 25, 2006

(54) Method and apparatus for connecting circuit cards employing a cooling technique to achieve desired temperature thresholds and card alignment

(75) Inventors: Len Marro, Poquott, NY (US); Robert Jung, Manorville, NY (US); Stanley Shan, Woodbury, NY (US); Richard Haining, Coram, NY (US)

Correspondence Address: VOLPE AND KOENIG, P.C., UNITED PLAZA, SUITE 1600, 30 SOUTH 17TH STREET, PHILADELPHIA, PA, 19103, US

(73) Assignee: Data Device Corporation, Bohemia, NY (US)

(21) Appl. No.: 11/264,424

(22) Filed: Nov. 1, 2005

Related U.S. Application Data
(60) Provisional application No. 60/624,371, filed on Nov. 2, 2004.

(51) Int. Cl. H05K 7/20

(52) U.S. Cl. 361/718; 361/719; 361/704

(57) ABSTRACT

Method and apparatus for interconnecting cards carrying heat generating ICs. A heat sink having a plurality of heat tubes is placed between two cards. The ICs are mounted “face down” so that the heat sink engages surfaces of the ICs opposite the surfaces having electrical and heat conductive terminals wherein an interstitial layer of a non-conducting, preferably gel-like material is placed between the heat sink and the surfaces of the ICs to alleviate mechanical stresses and enhance heat transfer. The thickness of the cards made of multiple conductive layers, separated by dielectric layers are controlled to provide cards of the same thickness. The heat sink provides proper spacing between and parallelism of facing surfaces of the cards to assure reliable connection and signal integrity between high speed connectors arranged on facing surfaces of the cards to electrically connect components from one board to the other.

This application claims priority from U.S. provisional application No. 60/624,371 filed on Nov. 2, 2004, which is incorporated by reference as if fully set forth.

### FIELD OF INVENTION

The present invention relates to circuit cards and more particularly to method and apparatus for joining circuit cards with high speed connectors and utilizing cooling means to assure operation within required temperature thresholds and designed to fit compactly within standardized mounting racks.

### BACKGROUND

Circuit cards containing a plurality of sophisticated integrated circuit (IC) chips are frequently mounted in racks, which require that the circuit cards be designed to meet size and dimensional constraints to assure the easy and proper installation of the cards into the racks. As one example, Versa Module European (VME) chasses are provided with chassis rails designed to support opposite parallel sides of IC bearing cards and to conduct heat from the ICs to the cards and then to the chassis. The cards that are connected to the chassis rails are required to operate with a maximum rail temperature of 85° C. It is therefore necessary to provide cards of the proper size and dimensions for use in VME chasses and further to assure that the cards are capable of operating at a given maximum rail temperature.

In addition, digital cards having high speed ICs must be connected by high density, fine pitch high speed connectors which are required to be positioned between the closely spaced cards. It is therefore extremely important to provide fiber channel matrix cards having a construction which assures precise alignment of the cards in order to assure proper alignment of the mating, high speed connectors.

### SUMMARY

The present invention is characterized by comprising a matrix card assembly which includes a heat sink capable of controlling the rail-to-junction temperature rise and causes heat generated by the matrix card ICs to be conducted to the heat sink and rails and thereby dissipated through the chassis in which the cards are arranged. The cards are characterized by a design whose thickness, together with the height of fully mated high speed connectors, is controlled so as to have a given pitch, i.e. separation distance between the bottom surfaces of mating cards in order to fit properly on the support rails of the chassis receiving the cards.

The heat sink has integral heat pipes that conduct heat generated by the ICs to the outer edges of the heat sink. The heat pipes are located directly above the ICs to optimize heat dissipation. An interstitial compressible material, such as a gel-like material preferably spread to as to take the form of a pad, is provided between the ICs and the heat sink to provide relief from mechanical stresses and further to enhance thermal transfer from the ICs to the heat sink. The spacing or gap between the heat sink and the surface of the ICs which is occupied by the interstitial material is minimized to provide maximum heat transfer.

Each matrix card comprises a plurality of alternating layers of conductors and dielectric, the dielectric layers serving as insulation between adjacent conductive layers and the conductive layers serving the function of either providing an electrical connection between an IC terminal or a heat sink for conducting heat from a surface of the IC engaging the card to convey the heat to the rails on opposite sides of the card and ultimately transfer the heat to the chassis.

### BRIEF DESCRIPTION OF THE DRAWING(S)

The invention will be best understood from a consideration of the accompanying figures wherein like elements are designated by like numerals and, wherein:

FIGS. 1A and 1B are perspective, exploded views showing one preferred embodiment of the card construction of the present invention.

FIG. 1C shows a sectional elevational view looking in the direction of arrows 1C, 1C in FIG. 1A.

FIG. 1D shows a sectional view of a typical heat pipe employed in the heat sink shown, for example, in FIG. 1A.

FIG. 2 is a schematic view showing the manner in which the matrix cards of the present invention are received by chassis rails of a chassis.

FIGS. 3A and 3B respectively show detailed views of the top and bottom surfaces of the lower card shown, for example, in FIG. 1A.

FIGS. 4A and 4B respectively show top and bottom views of the upper card shown, for example, in FIG. 1A.

### DETAILED DESCRIPTION OF THE PREFERRED EMBODIMENT(S)

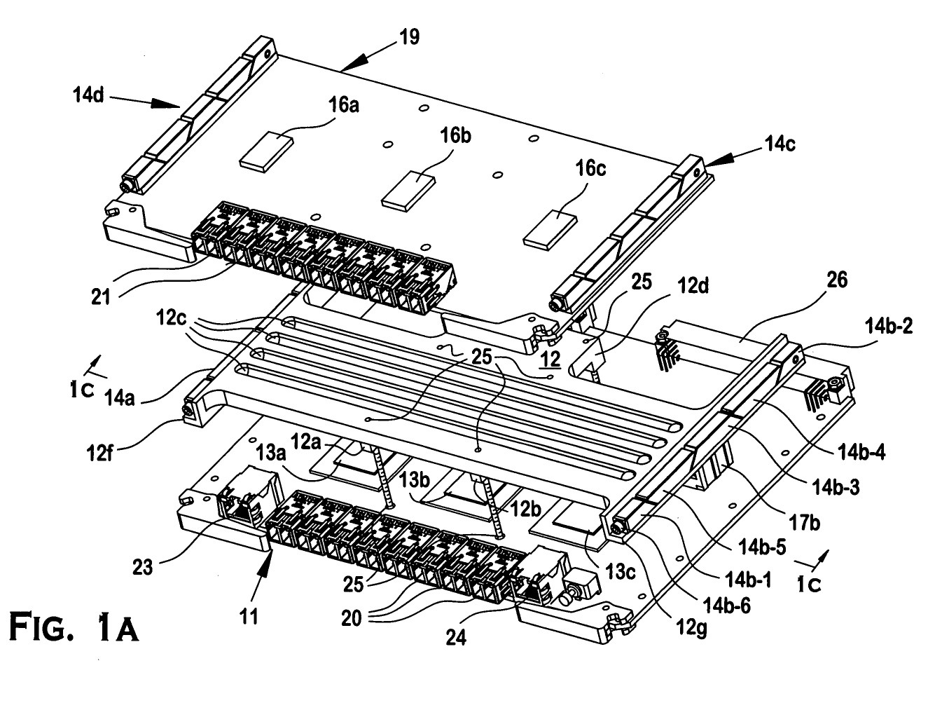

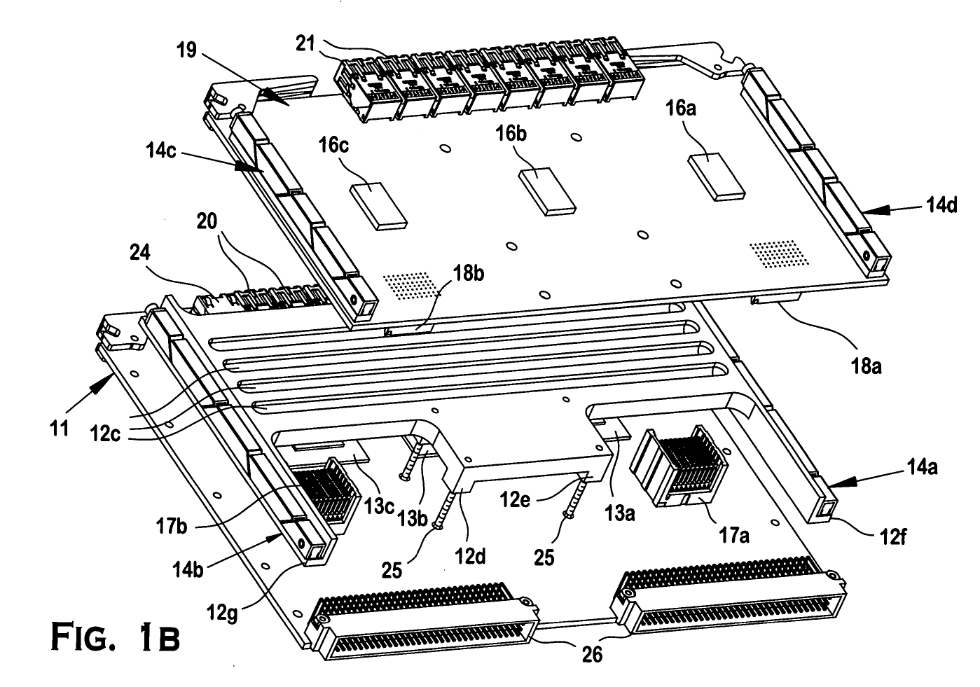

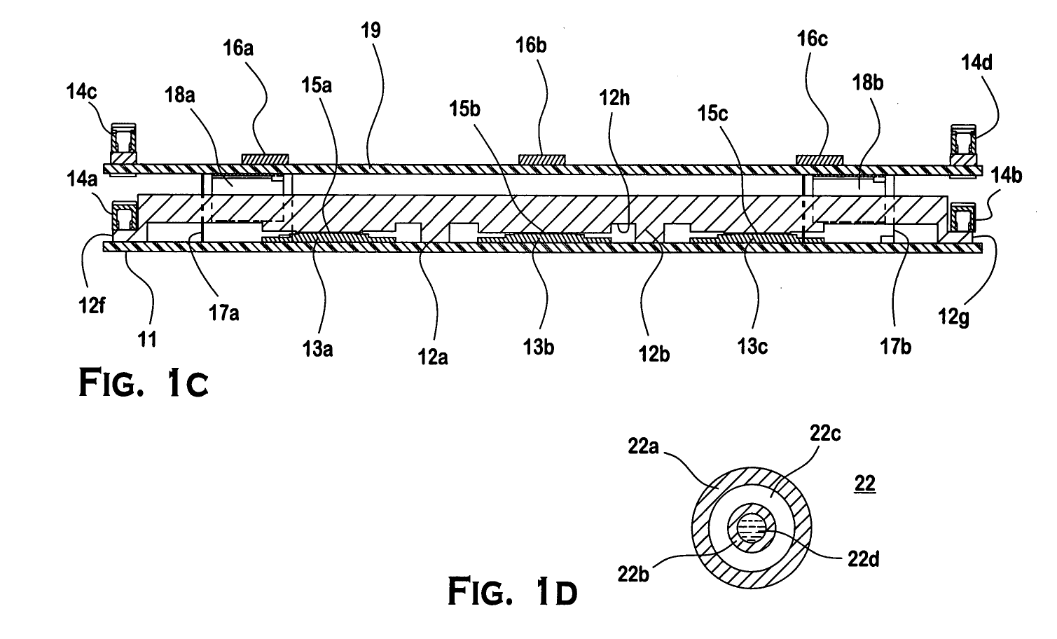

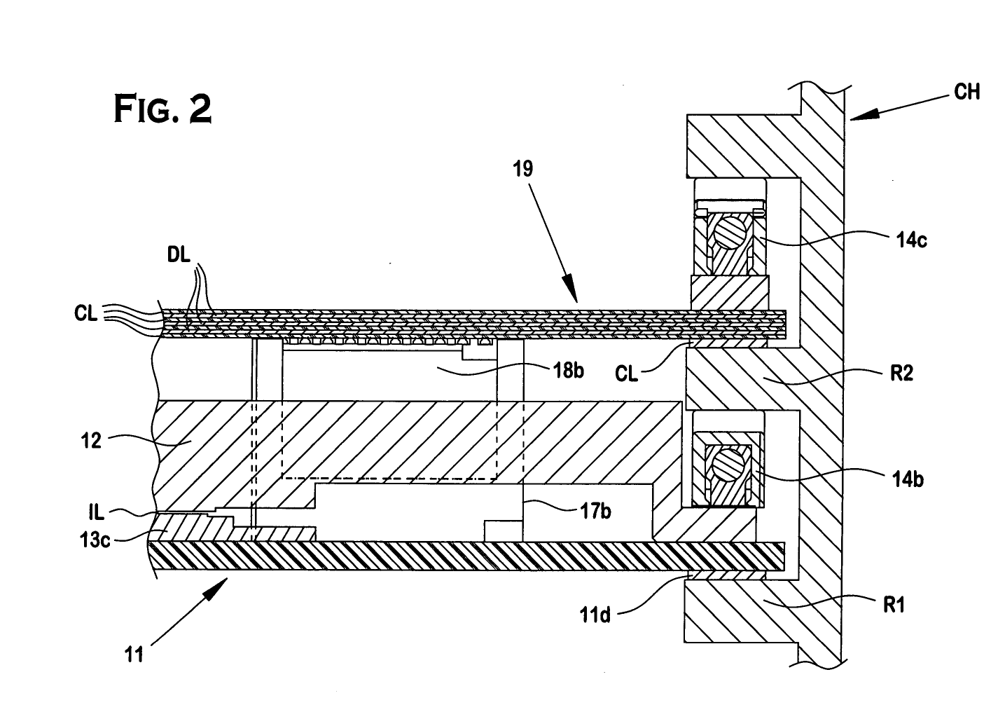

FIGS. 1A and 1B show one preferred embodiment 10 of the present invention which is comprised of a 16 port fiber channel matrix card assembly having two (2) high speed digital Versa Module European (VME) cards 11 and 19 which are interconnected with one another through the use of high density, fine pitch high speed connector assemblies which are well known in the art and will be described in greater detail below. The cards of the preferred embodiment 10 comprise a lower card 11 which is identified as a matrix card and an upper card 12 which is defined as a media card.

The card assembly 10 is designed to be installed in a dual VME chassis, partially shown in schematic fashion in FIG. 2, which chassis is designed to operate with a maximum rail temperature of 85° C.

Cards 11 and 19 are each comprised of a plurality of layers including conductive layers separated by dielectric layers, as will be described in detail below.

Matrix card 11 has a number of integrated circuit (IC) components, including several IC components that dissipate significant power in the form of heat. Among these components, for example, are the ICs 13a, 13b and 13c. The components 13a-13c may, for example, be field programmed gate arrays (FPGAs) each having Ball Grid Arrays (BGAs) and which dissipate a significant amount of power. In one example, these three (3) components dissipate a total of 20 watts. These three (3) FPGAs have a maximum junction temperature of 100° C. The maximum required 85° C. rail temperature of the rails provided on card 11 (and to be more fully described) coupled with the 100° C. maximum junction temperature gives a maximum allowable rail to junction rise of 15° C. Media card 19 also has a number of IC components, see arrays 16a, 16b, 16c, which, in the embodiment shown, do not dissipate a significant amount of heat.

In order to control the rail-to-junction rise, the assembly 10 is provided with a metallic conductive heat sink 12 preferably formed of aluminum and having a plurality of valleys 12c each receiving a heat pipe 22 integrally mounted in each of the valleys 12c.

FIG. 1D shows a cross-section of one of the heat pipes integrally mounted in one of the valleys 12c. The heat pipe 22 shown in cross-section is comprised of an outer aluminum pipe 22a and an inner aluminum pipe 22b. The interior 22c of inner pipe 22b is filled with water. The hollow annular region 22c between the inner pipe 22b and outer pipe 22a comprises an air space. The spacing between the pipes 22a and 22b is not critical.

The lower surface of heat sink 12 is provided with integral pedestals 12a, 12b, 12d and 12e arranged intermediate the opposing ends of heat sink 12 and is further provided at its left-hand and right-hand sides with integral, substantially L-shaped wedge lock supports 12f and 12g, the bottom surfaces of the aforementioned pedestals and supports engaging the top surface of card 11 and being designed so that the aforementioned pedestals and supports maintain the undersurface 12h a given distance above the top surface of card 11. Threaded members 25 threadedly engage tapped openings in the heat sink to secure the heat sink 12 to cards 11 and 19. The top card 19 has openings receiving the threaded members 25 and washers and threaded nuts (not shown) secure card 19 to heat sink 12. Counter sunk screws threadedly engage tapped openings in the members 25 and secure card 11 to heat sink 12. The openings in the cards 11 and 19 and the threaded members assure precise alignment of the boards 11 and 19 to thereby assure proper alignment of the high-speed connection 17a, 17b with 18a, 18b.

The heat sink 12 has a substantially E-shaped configuration when viewed from the top, as shown in FIG. 1B wherein the main body portion of the heat sink is positioned directly above the ICs 13a, 13b and 13c, enabling the heat pipes, which are located directly above the ICs 13a-13c, to optimize heat dissipation. The heat sink has two cut-away regions 12h and 12i to provide adequate clearance for a pair of high-speed connector halves 17a, 17b mounted upon the top surface of card 11 and electrically engaging contacts on the top surface of board 11 with associated terminals along a bottom surface of each of the connector halves 17a, 17b. The bottom surface of card 19 is provided with a pair of high speed connector halves 18a, 18b, shown best in FIG. 1C which have the terminals on their upper surfaces an electrical contact with terminals on the bottom surface of card 19 and which electrically and mechanically mate with the high speed connector halves 17a, 17b, as is well known in the art.

The VME specifications dictate a pitch of 0.800 inches between cards 11 and 19. The spacing from the bottom surface of media card 19 and the bottom surface of matrix card 11 is dictated by the height of the high speed connector halves 17a, 17b, 18a, 18b when fully mated. In one preferred embodiment this height is 0.710 inches. In order to obtain a pitch of 0.800 inches the cards 11 and 19 have their dielectric layers respectively adjusted and proportioned in order to achieve the precise space needed to ensure a reliable connection of the high speed connectors 17a-18a and 17b-18b and further to be properly received in the chassis rails to maintain signal integrity. Cards 11 and 19 are substantially the same thickness. In applications where one card has fewer conductive layers, the difference in thickness is made up by increasing the thickness of the dielectric layers. It can be seen that the combined thicknesses of the cards 11 and 19 is less than 0.100 inches. The interstitial layer (IL—see FIG. 2) in the preferred embodiment is preferably a gel-like substance which is applied upon the upper surface of the ICs such as the FPGAs 13a, 13b and 13c. The gel-like substance is thixatropic and remains fixed in place in the area where it is applied, i.e., it does not get squeezed out of the region between the heat sink and the surfaces of the FPGAs, 13a, 13b and 13c. The layer of gel-like substance effectively forms a “pad” between the opposing surfaces and compresses when the cards 11 and 19 are fastened to the heat sink. The “pads” are compressible and serve to completely fill any void between the top surfaces of ICs 13a-13c and the bottom surface of heat sink 12. The gap space between ICs and heat sink is typically in the range of from 0.002 inches to 0.007 inches. The pads compress more or less due to the size of the gap space. The pads are formed of a thermally conductive, electrically insulated dielectric gel-like, thixatropic material to facilitate good heat transfer and alleviate mechanical stresses which may occur in the card 11 and/or the ICs 13a-13c.

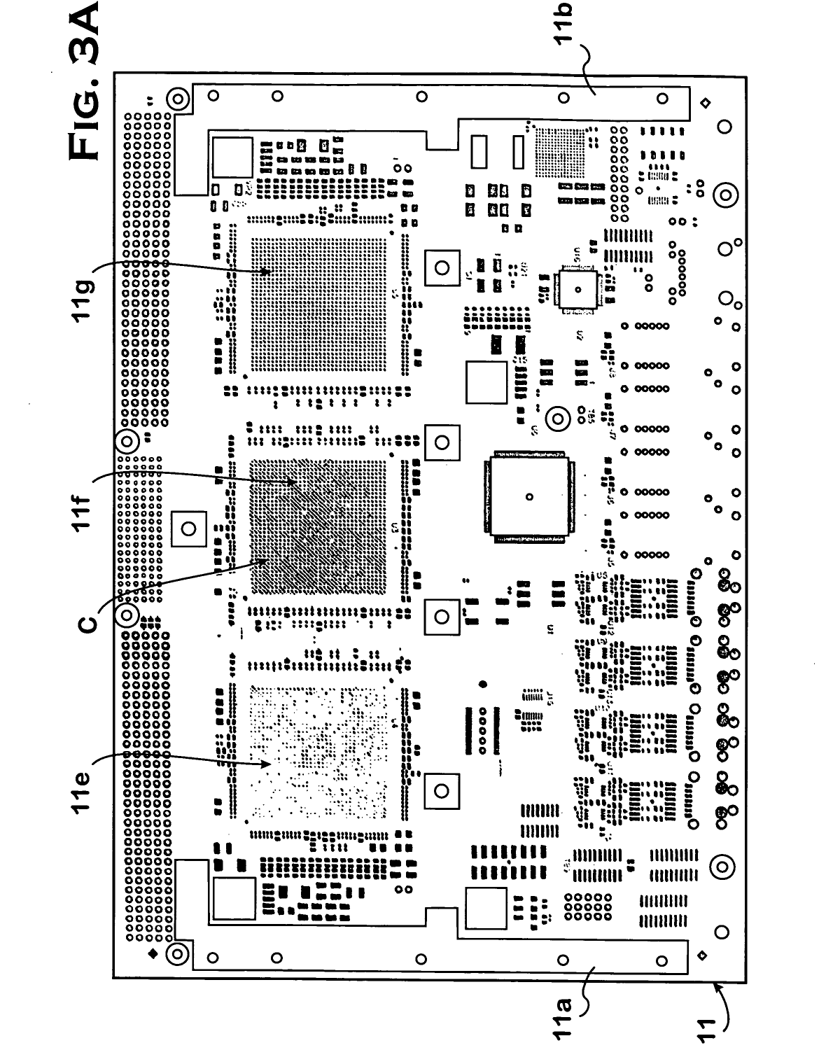

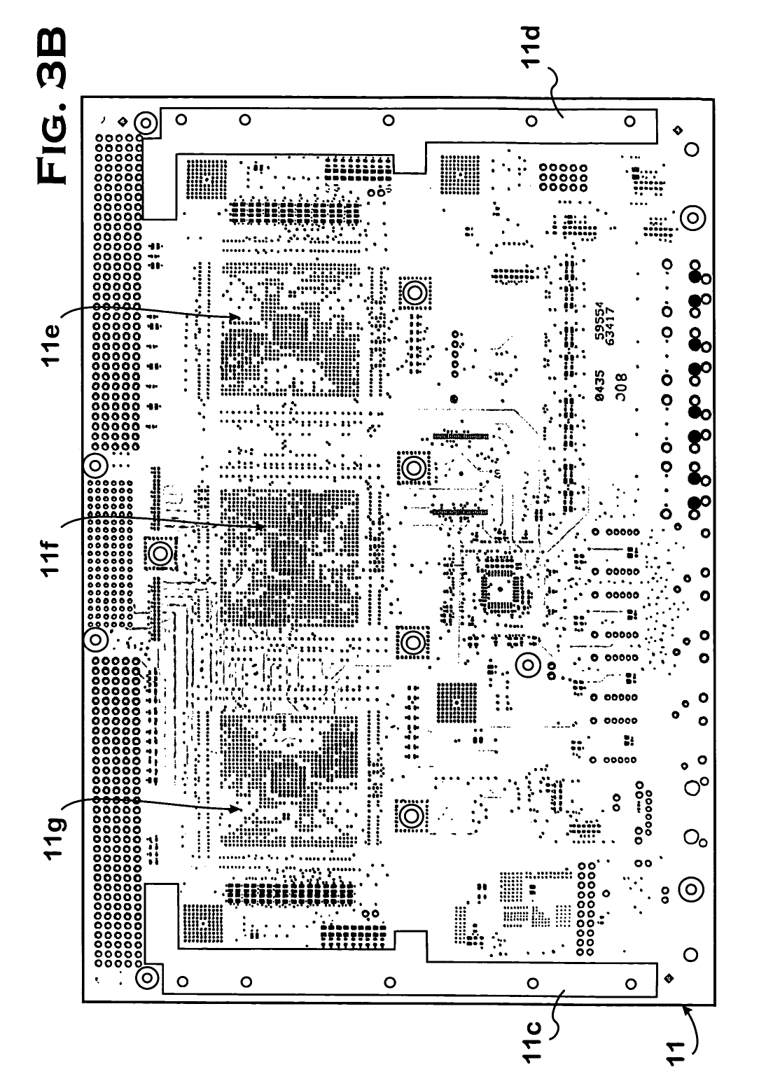

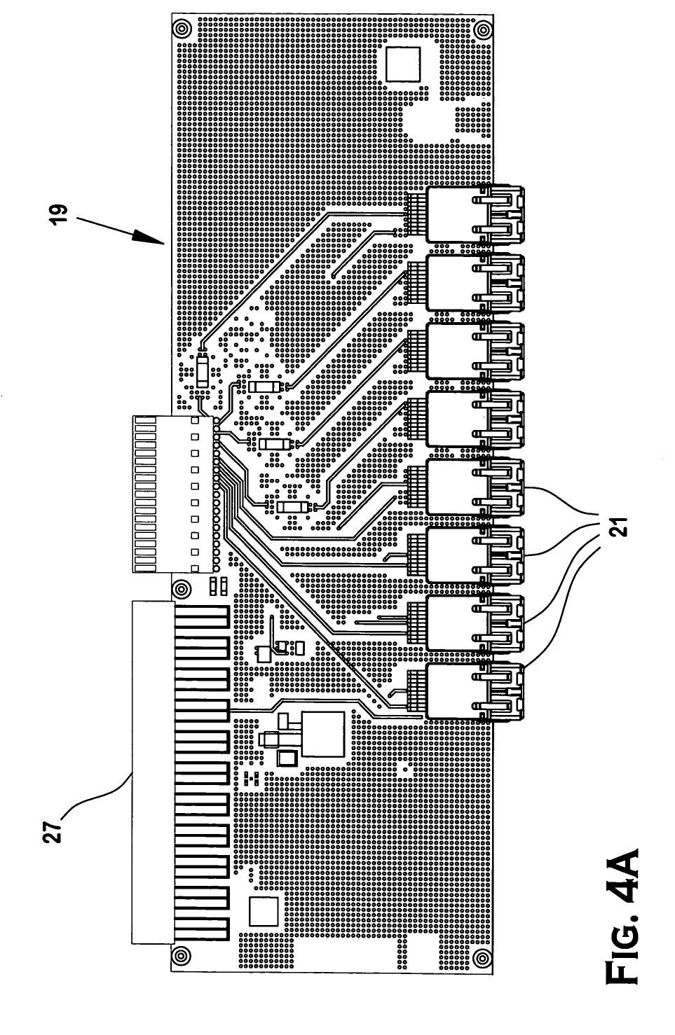

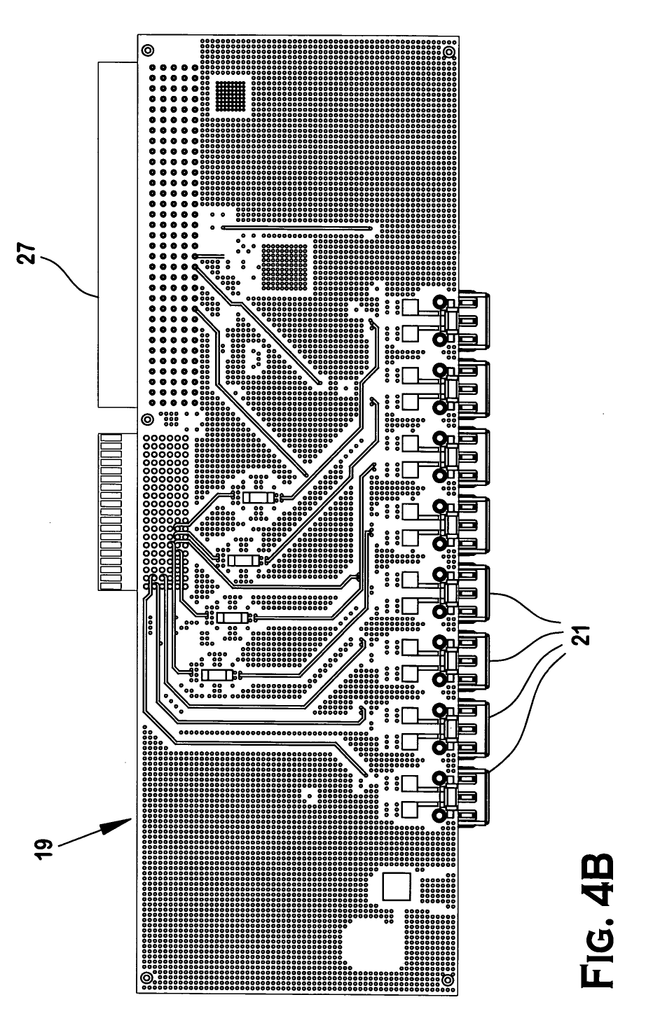

The substantially L-shaped supports 12f and 12g are each placed upon a conductive surface, such as, for example the conductive surfaces 11a, 11b of card 11, shown in FIG. 3A. The pedestals 12a, 12b, 12d, 12c and the L-shaped supports control the spacing between the top surface of card 11 and the bottom surface of the heat sink 12. The interstitial layer fills this gap space which is typically in the range of 0.002 to 0.007 inches.

Wedge locks 14a, 14b are mounted upon the L-shaped supports 12f and 12g and are designed to lock board 11 into place on the chassis rails. It should be noted that wedge locks 14a and 14b, as well as wedge locks 14c and 14d provided on card 19 are identical in both design and function and only one wedge lock will be described herein for purposes of simplicity.

FIG. 2 shows the right-hand ends of the cards 11 and 19 of assembly 20 and the manner in which the cards slide into slots in the chassis CH. It should be understood that the left and right-hand ends of the cards are mounted into the chassis in the same fashion. The conductive area 11d on the bottom surface of card 11 rests upon the upper surface of rail R1. The top of wedge lock 14b lies beneath the underside of rail R2. Wedge lock 14b is operated to urge sections thereof upwardly against the bottom of rail R2, urging conductive area 11d of card 11 into intimate engagement with rail R1. Wedge lock 14c is operated in a similar manner to urge a bottom conductive layer CL of card 19 in intimate engagement with rail R2. The required spacing (i.e., “pitch”) between cards 11 and 19, controlled by the top surface of the heat sink engaging the bottom surface of card 19 and the surfaces of the pedestals 12a, 12b, 12d, 12e and wedge lock supports 12f, 12g engaging the top surface of card 11 assures accurate alignment of the cards 11 and 19 with rails R1 and R2, as well as assuring the proper mating of connectors 17a, 17b and 18a, 18b. FIG. 2 shows the layers of card 19 in some detail wherein the conducting layers CL are spaced from the dielectric layers DL wherein the dielectric layers are reduced in thickness to accommodate a larger number of conductive layers or are increased in thickness to accommodate a smaller number of conductive layers and so as to provide cards of uniform and equal thickness, even though the cards have different numbers of conductive layers.

Wedge lock 14b has end portions 14b-1 and 14b-2 and an intermediate section 14b-3 which are secured in place upon card 11 through suitable fasteners (not shown) which are formed of a suitable conductive material, such as aluminum, to conduct heat from heat dissipating conductive layers in card 11 to the heat sink 12 and conductive wedge lock 14b to the chassis wheel engaging the wedge lock.

By tightening the threaded member 14b-6, end members 14b-1 and 14b-2 are drawn toward the common central member 14b-3 whereupon the diagonally aligned end surfaces of member 14b-4 and 14b-5 slide along the diagonally inclined surfaces of members 14b-1, 14b-2 and 14b-3 causing the members 14b-4 and 14b-5 to be lifted and thereby causing the wedge lock 14b to urge card 11 downwardly so as to be locked in place by the aforementioned wedging action. The conductive areas 11c, 11d on the bottom surface of card 11, shown in FIG. 3A intimately engage the conductive rail to conduct heat from opposite ends of the card 11 to the chassis rails.

Heat sink 12 conducts heat to the rails of the VME chassis by the wedge locks 14a, 14b and the conductive areas 11a-11d of card 11, whereby any heat generated by the ICs on matrix card 11 is dissipated through the VME chassis. Heat sink 12 is designed so that it mates directly to each of the FPGAs 13a-13c with an interstitial material 15 provided between the exposed surfaces of the FPGAs 13a-13c and the under surface 12h of heat sink 12 in order to provide relief from mechanical stresses. The interstitial material is also chosen to enhance thermal transfer between the FPGAs 13a-13c and the heat sink 12. The precise spacing or gap between the heat sink 12 and the upper surfaces of the FPGAs 13a-13c is minimized in order to assure maximum heat transfer between the FPGAs and the heat sink 12. This arrangement ensures maximum heat transferred to the VME chassis rails while maintaining the rail temperature at the required 85° C.

The card 11, in the embodiment shown, is provided with eight (8) optical ports 20 arranged along one edge of card 11 to provide signal transmission to the outside world. Each of the devices that comprise an optical port dissipates 0.7 watts for a total of 5.6 watts for the ports 20 on card 11. All of the heat energy in ports 20 is dissipated into the matrix card 11 and carried by way of thermal planes, provided in internal layers of card 11, to the conductive areas 11a-11d along the side edges of card 11 and ultimately is conducted to the VME chassis rails. The heat carried away from the energy dissipating device (i.e., IC) is transferred through heat conductors directly engaging a heat conducting surface of the IC, which heat conductors extend into the card 11 and are conductively connected to a given thermal plane provided in one of the multiple layers of card 11, which thermal plane conducts the heat to the conductive areas 11c and 11d at opposite side edges of the card and then to the VME chassis rails.

It should be noted that the FPGAs 13a, 13b and 13c are arranged on card 11 so that the surface carrying the electrical terminals and heat conducting terminals are arranged face down so as to electrically engage the thermal or electrical conductor associated therewith and provided along the upper surface of card 11. Making reference to FIG. 3A, card 11 has three (3) areas 11e, 11f and 11g each for receiving an associated one of the ICs 13a, 13b and 13c. Since the electrical connecting techniques are substantially similar in nature, only one IC connection operation will be described herein for purposes of simplicity.

Making reference to area 11f on the top surface of card 11, an array of conductive contacts is arranged in a regular matrix and occupy a rectangular-shaped region. Each of the conductive contacts is positioned to be engaged by an associated spherical-shaped conductive member or “ball,” provided on the engaging surface of the FPGA placed upon area 11I. Each ball is coupled to an associated terminal along the downwardly directed surface of the FPGA 13b. The balls are the order of 0.022 inches in diameter and provide an electrical path between an associated terminal of the FPGA 13b and a conductive contact surface C in area 11f. Each contact surface C is electrically coupled to one of the layers of card 11. Similarly, a ball which serves as a heat conductor engages a heat dissipating point along the downwardly directed surface of FPGA 13b and conducts this dissipated energy to an associated contact in surface area C which conducts heat to one of the thermal planes making up the plurality of layers of card 11, which thermal plane conducts the heat to areas 11c, 11d and ultimately to the chassis rails.

The upper surface of card 11 and the facing board surface of card 19 are maintained in spaced, substantially parallel fashion by the opposing surfaces of heat sink 12. The precise pitch assures that the cards 11 and 19 will not be skewed relative to one another to thereby assure that the connector halves 17a, 17b precisely mate with one another to assure reliable connection of the high speed connectors and to maintain signal integrity.

Board 11 is further provided with a pair of electrical connectors 23, 24 for providing electrical connections between the outside world and the devices on card 11. Connectors 26 on the opposite parallel edge of card 11 provide electrical connection with electrical devices in the chassis.

The media card 19 is likewise provided with eight (8) optical ports which, similar to matrix card 11 dissipate of the order of 5.6 watts conducted to opposite sides of card 19 by thermal planes making up selected layers of card 19. Card 19 is likewise provided with wedge locks 14c and 14d for locking card 19 to associated chassis rails of the VME chassis in the manner described above.

The arrays 16a, 16b and 16c of ICs are arranged on the upwardly directed surface of card 19 and the heat energy dissipated from these ICs is minimal. The upwardly directed surface of heat sink 12 directly engages the downwardly directed surface of card 19 and does not require an interstitial layer.

Card 19 may also be provided with one or more connectors 27, similar to connectors 26, to couple devices on card 19 to devices in the VME chassis.

Although the preferred embodiment shows a card assembly comprised of two cards with an interspersed heat sink, it should be understood that three (3) or more cards may be assembled in the manner shown and described above, utilizing a heat sink between adjacent cards and providing an interstitial layer to relieve mechanical stresses and enhance thermal transfer from the ICs to the heat sink.

What is claimed is:

1. A method for assembling first and second circuit cards each having a plurality of integrated circuits (ICs), comprising:
providing a heat sink;
positioning said heat sink between said first and second circuit cards;
providing a compliant interstitial layer between one surface of the heat sink and a surface of at least one IC of said first card; and
securing the cards to the heat sink to maintain the cards in spaced parallel fashion, a given distance apart.

2. The method of claim 1 wherein securing the cards to the heat sink further comprises:
compressing the compliant layer between the heat sink and said surface of said at least one IC.

3. The method of claim 2 wherein compressing the compliant layer comprises:
compressing the compliant layer so as to substantially completely fill any gap space between the heat sink and said surface of said at least one IC.

4. The method of claim 1 wherein the step of providing said interstitial layer, comprises:
providing a layer of a non-metallic material having a characteristic of providing good heat transfer from said at least one IC to said heat sink.

5. The method of claim 1 further comprising:
providing a pair of conductive members along opposite sides of said card having said at least one IC; and
placing opposite ends of said heat sink on said pair of conductive members.

6. The method of claim 1, wherein providing a heat sink, further comprises:
providing a conductive member;
forming valleys in said conductive member;
providing a plurality of heat tubes; and
placing each heat tube in one of said valleys.

7. The method of claim 6 further comprising:
placing the valleys containing said heat tubes directly above said one IC.

8. The method of claim 6 wherein providing heat tubes further comprises:
forming each heat tube of a conductive tubular member; and
filling each heat tube with a coolant.

9. The method of claim 6 further comprising:
inserting each heat tube in a hollow conductive outer tube surrounding said heat tube, the space between said heat tube and said outer tube being an air space.

10. The method of claim 4 wherein the step of providing said conductive members further comprises:
arranging said conductive members along opposite sides of one surface of said first card having said at least one IC; and
securing said heat sink to said first card and upon said conductive members to conduct heat from opposite ends of said heat sink to said conductive members.

11. The method of claim 10 wherein providing said first and second cards further comprises:
providing said first and second cards with a plurality of conductive layers separated by dielectric layers; and
coupling at least one of said conductive layers to one of said conductive members to conduct heat in said at least one conductive layer to said one of said conductive members.

12. The method of claim 5, further comprising:
providing wedge locks;
mounting said wedge locks upon opposite ends of said heat sink; and
operating said wedge locks when the card is mounted in a chassis to lockably engage support rails of said chassis.

13. The method of claim 1 further comprising:
providing said at least one IC with a grid-like array of electrical/heat terminals on one major surface thereof;
providing a grid like array of terminals on said first card for joining with associated electrical/heat terminals of said at least one IC, said interstitial layer engaging a remaining major surface of the IC opposite said one major surface.

14. The method of claim 13 further comprising:
providing a ball grid array (BGA) comprised of a plurality of conductive balls arranged in grid-like fashion;
placing the BGA between the electrical/heat terminals on said IC and the grid-like array of terminals on said first card to connect electrical/heat terminals on said IC with associated electrical/heat terminals on said first card.

15. The method of claim 1 wherein the step of securing the first and second cards to the heat sink comprises:
providing threaded members which extend through and threadedly engage said heat sink to as to have first ends adapted to extend through a first group of associated openings in the first card arranged on one side of said heat sink and second ends adapted to extend through a second group of associated openings in the second card arranged on a side opposite said one side of said heat sink; and
securing said first and second cards to the heat sink.

16. The method of claim 15 further comprising:
positioning the first and second groups of openings in a manner to assure proper alignment of said first and second cards.

17. An assembly comprising:
first and second circuit cards each having a plurality of integrated circuits (ICs);
a heat sink positioned between said first and second circuit cards;
a compliant interstitial layer between one surface of the heat sink and a surface of a least one IC of said first card; and
said cards being secured to the heat sink to maintain the cards in spaced parallel fashion a given distance apart.

18. The assembly of claim 17 further comprising:
said compliant layer being compressed between the heat sink and said one surface of said at least one IC.

19. The assembly of claim 18 wherein:
said compliant layer is compressed so as to substantially completely fill any gap space between the heat sink and said surface of said at least one IC.

20. The assembly of claim 17 wherein said interstitial layer comprises:
a gel-like layer of a compressible material having a characteristic of providing good heat transfer from said at least one IC to said heat sink.

21. The assembly of claim 20 wherein said layer is a fixatropic gel.

22. The assembly of claim 17 further comprising:
a pair of conductive members arranged along opposite sides of said first card; and
opposite ends of said heat sink being mounted on said pair of conductive members.

23. The assembly of claim 17, said first and second cards comprising:
a plurality of conductive layers each separated by dielectric layers.

24. The assembly of claim 23 wherein one of said first and second cards has a greater number of conductive layers than a remaining one of said first and second cards; and
the dielectric layers being adjusted in thickness so that a total thickness of said first card and a total thickness of the second card are substantially equal.

25. The assembly of claim 17 wherein said heat sink further comprises:
a conductive member having a plurality of valleys; and
a plurality of heat tubes each placed in one of said valleys.

26. The assembly of claim 25 further comprising:
said valleys containing said heat tubes being positioned directly above said one IC.

27. The assembly of claim 25 wherein said heat tubes further comprise:
a conductive tubular member filled with a coolant.

28. The assembly of claim 27 wherein said coolant is water.

29. The assembly of claim 25 wherein further said heat tube further comprises:
a hollow conductive outer tube surrounding said heat tube, the space between said heat tube and said outer tube being an air space.

30. The assembly of claim 20 wherein said conductive members are
arranged along opposite sides of one surface of said first card having said at least one IC; and
said heat sink being mounted on the conductive members of said first card to conduct heat from opposite ends of said heat sink to said conductive members.

31. The assembly of claim 30 wherein said first and second cards each further comprise:
a plurality of conductive layers separated by dielectric layers; and
at least one of said conductive layers being coupled to one of said conductive members to conduct heat in said at least one conductive layer to said one of said conductive members.

32. The assembly of claim 31 wherein one of said first and second cards has a greater number of conductive layers than a remaining one of said first and second cards; and
the dielectric layers being adjusted in thickness so that a total thickness of said first card and a total thickness of the second card are substantially equal.

33. The assembly of claim 22 further comprising:
wedge locks mounted upon opposite ends of said heat sink, each wedge lock having operating means to move the wedge lock into a wedging position.

34. The assembly of claim 17 further comprising:
said at least one IC having a grid-like array of electrical/heat terminals on one major surface thereof;
a grid-like array of terminals arranged on said first card for joining with associated electrical/heat terminals of said at least one IC; and
said interstitial layer engaging a remaining major surface of the IC opposite said one major surface.

35. The assembly of claim 34 further comprising:
a ball grid array (BGA) comprised of a plurality of conductive balls arranged in grid-like fashion;
said BGA being placed between the electrical/heat terminals on said IC and the grid-like array of terminals on said first card to connect electrical/heat terminals on said IC with associated electrical/heat terminals on said first card.

36. The assembly of claim 17 further comprising:
threaded members extending through and threadedly engaging threaded openings in said heat sink and having first ends extending through a first group of associated openings in the first card arranged on one side of said heat sink and second ends extending through a second group of associated openings in the second card arranged on a side opposite said one side of said heat sink; and
fasteners for securing said first and second cards to the heat sink.

37. The assembly of claim 36 further comprising:
said first and second groups of openings being positioned to assure proper alignment of said first and second cards.

38. The assembly of claim 17 further comprising at least one high speed connector comprised of first and second connector halves respectively arranged on facing surfaces of said first and second cards;
said first connector half being electrically coupled to electric terminals on said first card;
said second connector half being electrically connected to electrical terminals said second card;
said connector halves being electrically connected when the first and second cards are secured to said heat sink to provide electrical connections between said first and second cards.

39. The assembly of claim 38 where in said heat sink is configured so that the facing surfaces of the first and second cards upon which the high speed connector halves are mounted are substantially parallel to one another and are spaced apart by a distance to assure proper electrical connection of the high speed connector halves when the first and second cards are properly secured to said heat sink.
